(19) United States
(12) Patent Application Publication
(10) Pub. No.: US 2012/0326116 A1
(43) Pub. Date: Dec. 27, 2012

(54) SEMICONDUCTOR DEVICE AND METHOD OF MANUFACTURING A SEMICONDUCTOR DEVICE

(75) Inventors: David Julian Peter Ellis, Cambridgeshire (GB); Anthony John Bennett, Cambridgeshire (GB); Andrew James Shields, Cambridgeshire (GB)

(73) Assignee: Kabushiki Kaisha Toshiba, Tokyo (JP)

(21) Appl. No.: 13/504,734

(22) PCT Filed: Nov. 30, 2010
(86) PCT No.: PCT/GB10/02205

§ 371 Date: Aug. 28, 2012

(30) Foreign Application Priority Data
Mar. 12, 2010 (GB) 1004164.8

(51) Int. Cl. H01L 33/04; B82Y 99/00; B82Y 40/00

(52) U.S. Cl. 257/9; 438/22; 257/E33.005; 977/774

(57) ABSTRACT

A semiconductor structure with a waveguide, the semiconductor structure has a plurality of layers, at least one of which being partially laterally oxidised, said laterally oxidised material modifying the lateral effective refractive index with said structure in order to form a waveguide within the structure, the structure also has a quantum dot, said quantum dot being configured to emit photons into said waveguide, the waveguide being configured such that it guides the output from a single quantum dot.

### TECHNICAL FIELD

Embodiments of the present invention generally relate to quantum optical circuits.

### BACKGROUND ART

The field of quantum optics is becoming more and more commercially relevant with the increasing advances in quantum cryptography, quantum computing and other photonic based technologies. Typically such technologies involve one section where photo generation occurs, a second section where photon manipulation occurs and a third section where photon detection occurs. Transport of photons between these systems using free space provides disadvantages in that such free space systems are bulky and require careful alignment and good mechanical stability. Fibre optics reduce these problems, but generation, manipulation and detection of the light often requires the fibre to be pigtailed to some other opto-electronic device.

### CITATION LIST

Park et. Al “Low-Threshold Oxide-Confined 1.3 μm Quantum-Dot Laser”, IEEE Photonic Technology Letters Vol 13, No. 3, March 2000.
U.S. Pat. No. 5,403,775

### BRIEF DESCRIPTION OF THE DRAWINGS

The present invention will now be described with reference to the following non-limiting embodiments in which:

FIG. 1 is a schematic of a semiconductor structure comprising a waveguide which has been formed by oxidation;

FIG. 2 is a schematic of an oxidation process which may be used for fabricating structures in accordance with an embodiment of the present invention;

FIG. 3a is a schematic of a semiconductor structure with a waveguide showing the layer structure of the device of FIG. 1 with the addition of a tapered oxide profile and

FIG. 3b a plot for refractive index against lateral position of the device of FIG. 1;

FIG. 4a is a schematic of a semiconductor structure with a waveguide in which both lateral and vertical optical confinement is provided by means of an oxidised material and

FIG. 4b shows a layer structure of the device of FIG. 4a prior to oxidation of said oxidisable material;

FIGS. 5(a) to 5(c) schematically illustrate fabrication stages in the fabrication of a device according to an embodiment of the present invention;

FIGS. 6(a) to 6(e) show variations on a device in accordance with an embodiment of the present invention;

FIG. 7 is a schematic showing the basic stages of a quantum optical process;

FIG. 8a is a schematic of a semiconductor structure in accordance with an embodiment of the present invention comprising a photon source located in a waveguide,

FIG. 8b is a schematic of a semiconductor structure in accordance with an embodiment of the present invention which comprises a photon source and a waveguide where photons travel from the photon source evanescently into the waveguide, and

FIG. 8c is a semiconductor structure in accordance with an embodiment of the present invention having a photon source in a circular waveguide;

FIG. 9 is a schematic of a photon source with two orthogonal waveguides;

FIG. 10a is a schematic of horizontally coupled waveguides and

FIG. 10b is a schematic of vertically coupled waveguides;

FIG. 11a is a schematic of horizontally coupled waveguides which are coupled evanescently and

FIG. 11b is an arrangement of waveguides which are vertically coupled;

FIG. 12a is a schematic of a semiconductor structure having a waveguide and phase shifter and

FIG. 12b is a schematic of a semiconductor structure with a waveguide and a cavity located near the waveguide to vary the refractive index of the waveguide;

FIG. 13 is a schematic of the layout of a semiconductor structure in order to produce a random number generator or a Hanbury-Brown Twiss Interferometer;

FIG. 14 is a schematic of an on-chip interferometer suitable for use in quantum cryptography;

FIG. 15 is a schematic of a photonic transistor;

FIG. 16 is a schematic of an optical filter element;

FIG. 17 is a schematic of an arrangement which allows a semiconductor structure to be coupled to an optical fibre,

FIG. 17(a) is a plan view and

FIGS. 17(b) and (c) are cross sections; and

FIG. 18 is a schematic of a wafer bonding technique for coupling emission from one waveguide into a separate chip.

### DETAILED DESCRIPTION

According to one embodiment, a semiconductor structure comprising a waveguide is provided, said semiconductor structure comprising a plurality of layers, at least one of which being partially laterally oxidised, said laterally oxidised material modifying the lateral effective refractive index within said structure in order to form a waveguide within said structure, the structure further comprising a quantum dot, said quantum dot being configured to emit photons into said waveguide, said waveguide being configured such that it guides the output from a single quantum dot.

Thus in a single integrated component, a photon source is provided such that its output is guided away from the source using a waveguide. The waveguide is formed by oxidation.

In an embodiment, such waveguides will be produced with the following restrictions such that only a single propagating optical mode is produced.

Consider a simple symmetric planar waveguide, containing a cladding region with refractive index n₁ and a waveguiding core with refractive index n₂ and of width 2d. Said waveguide is required to simultaneously satisfy the following equations:

(ad)²+(bd)²=(n₂²−n₁²)k₀²d²

and ad=bd tan(bd)
where a, b are constants to be determined and k₀=2π/λ where λ is the operation wavelength.

For single mode operation, acceptable solutions satisfy 0<√(n₂−n₁)·k₀d<π

The layer or layers within which the oxidised material is formed will comprise a material such as AlGaAs, AlAs, InAlAs, InAlGaAs, InAlAsP, AlP or AlAsSb with an aluminium content >70%.

Upon oxidation of this structure, the layer partially oxidises in a lateral direction, i.e. from the exposed edges inward. This allows the formation of a narrow channel, circle or other shape which is surrounded by the oxide material. This allows a waveguide to be produced. The size of the channel, circle, etc., can be carefully controlled using the oxidation time.

By varying the Al content in the oxidation layer, it is possible to vary the extent of oxidation which can be achieved during the oxidation process. This is because a layer with a lower Al content will oxidise slower and therefore can be more carefully controlled. In some embodiments, layers with varying Al concentrations may be used such that variable oxidation rates are present in order to control the profile of the resulting oxidised region.

The photons will be transmitted down an optical waveguide mode within said waveguide structure confined to a region of high effective refractive index compared to that of the surrounding layers after oxidation, said optical mode being strongly confined within said waveguiding region in the out of plane direction. The optical mode also being laterally confined to a region defined between the oxidised regions. The presence of these oxidised regions in proximity to said waveguide layer will cause the effective refractive index in the entire waveguide structure to be varied across the plane of the structure. The optical mode is then laterally confined by said variation in effective refractive index.

In an alternate embodiment, the optical mode may be confined in both lateral and vertical directions between regions of oxidised material. The waveguide may be located vertically between a pair of cladding layers, and said waveguide is itself partially oxidised.

As previously mentioned, the above waveguide is used to guide photons away from a photon source. The waveguide may be additionally used to manipulate these photons further or direct them into a further component.

The further component may be configured to receive photons, said waveguide being configured to guide said photons towards said component. Said further component may be a detector, comprising a plurality of layers configured for the absorption of photons. Said detector may comprise a plurality of quantum dots, an absorber layer and electrical contacts such that an electrical output is produced upon the detection of incident photons via carrier multiplication.

In the photon source, the active component is a semiconductor quantum dot, embedded within the waveguide or close enough to the waveguide so that the waveguide guides the photons emitted by the quantum dot. The spatial location of said quantum dot would be identified prior to waveguide fabrication such that the waveguiding structure may be accurately positioned relative to the quantum dot. The location of said quantum dot could be identified by studying the unprocessed semiconductor wafer, of by the use of quantum dots grown such that they form in pre-determined positions.

In an embodiment with a simple waveguide and a photon source emitting into the waveguide, the structure comprises a mesa and said quantum dot is provided along a central line through said mesa. In an embodiment, the single active semiconductor quantum dot is spatially aligned to said waveguide. The single active semiconductor quantum dot may be spectrally matched to said waveguide.

In further embodiment, the structure comprises an electrical contact, said electrical contact being configured supply carriers to said single quantum dot. The contact may be configured such that said electrical contact only supplies carriers to said single quantum dot.

The quantum dot may be optically excited to produce photons, in such an embodiment, the structure further comprises an aperture aligned with said single quantum dot such that said dot may be irradiated.

The photon source may be provided adjacent the waveguide and positioned to allow evanescent coupling between the photon source and the waveguide. In an alternative embodiment, photons can couple to a circular waveguide mode.

In a further embodiment, two orthogonal waveguides are coupled to an entangled photon source such that one photon from a pair exits through one waveguide and the other photon exits through the second waveguide. For example, said structure may comprise first and second orthogonal waveguides which are joined at a vertex and a source of entangled photons provided at said vertex.

It is possible to form splitters and couplers using coupled waveguides. The waveguides may be horizontally coupled where they are provided within the same plane or vertically coupled where they are provided in layers. In an embodiment, the coupled waveguides are close enough to each other at at least one point along their length to allow evanescent coupling to occur between the waveguides. In an embodiment, said structure contains no gain nor absorption region. Thus, a photon which is travelling in one waveguide may or may not transfer to the other waveguide at a certain point. Similarly, photons travelling in both waveguides may become mixed at these coupling points.

In an embodiment, a phase shifting element is formed by either electrically inducing a change of the refractive index using an electrical contact or the like or by placing a cavity, absorber or heating pad close to the waveguide in order to effect local changing of the refractive index.

Using the best building blocks, it is possible to manipulate devices in accordance with embodiments of the present invention to provide a:

1. On-chip quantum random number generators;
2. On-chip photon guiding to a certain waveguide;
3. On-chip Hanbury-Brown Twiss measurement;
4. On-chip quantum cryptography;
5. Photon transistor;
6. On-chip photon filtering;
7. Fibre coupling; and
8. Improve transportation using chip to chip coupling.

To realise a random number generator or the like, a beam splitter as described above is operated as a 50/50 splitter, the photon source is coupled to an end of said first waveguide and a detector is coupled to the other end of said waveguide. A second detector is coupled to the end of said second waveguide where the photons are expected to exit.

In a further embodiment an interferometer is provided which comprises first and second waveguides provided with at least one layer and being laterally confined within the plane of the layers by an oxidised material, said waveguides being coupled at two points along the length of the phase shifting element being provided in at least one of the waveguides between said coupling points. The two arms of the waveguide of the interferometer, which is the distance between the two coupling points, may be of the same length or different lengths dependent on the requirements. For quantum cryptography, the above interferometer may be used to time and phase entangle the photons and in this situation, the arms will be of different lengths. For photon guiding, the arms may be of the same length where switching the phase element between a 0° phase shift and a pi phase shift will result in the photon being emitting by different arms.

In a further embodiment, a photon filter may be provided using the above arrangements. Said filter comprises a plurality of opposing mirrors provided across said waveguide. Said mirrors may be provided by etching said waveguide. Such a filter will act as a fabry-perot etalon.

According to one embodiment a method of fabricating a semiconductor structure comprising a waveguide is provided, said method comprising:
forming a plurality of semiconductor layers incorporating an oxidisable layer and a quantum dot in one of said layers;
etching a pattern in said oxidisable semiconductor layer aligned with said quantum dot; and
oxidising said oxidisable semiconductor layer to produce a waveguide which is laterally bounded by the effective refractive index variation due to the presence of said oxidised material, the quantum dot being aligned with said waveguide such that said quantum dot outputs photons to said waveguide.

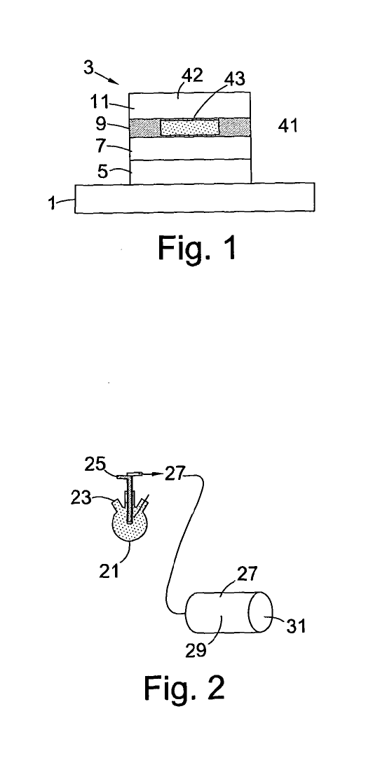

FIG. 1 is a schematic of a device having a waveguide formed by oxidation. This figure will be used to explain the processing steps used to form the waveguides.

The device is formed on a substrate 1. In this example, the substrate is GaAs, but other substrates could be used. A layer structure 3 is then grown. In this particular example, the layer structure comprises a lower Bragg mirror 5, GaAs layer 7, oxidation layer 9 which comprises AlAs. The content of Al in this oxidation layer 9 is to allow oxidation of the layers which will occur for all compounds with Al>70%. An upper Bragg mirror 11 is formed overlying the oxidation layer 9.

In this particular example, the oxidation layer is AlAs, but other structures are possible providing that the Al contribution is >70%. The system could be any III/V system. The oxidation layer 9 would typically comprise AlAs and AlGaAs, but could also include InAlGaAs, AlP, AlAsSb again with Al content >70%. Non-oxidizable layers surrounding the waveguide may comprise GaAs, AlGaAs, phosphides, antimonides with Al content <<70%.

In order to fabricate the waveguide, the structure is etched to form a suitable outer shape for the waveguide. In this particular example, the mesa is in the form of a long ridge.

This is achieved by patterning the structure using one the standard techniques such as photolithography or electron beam lithography and then etching the desired shape using either a dry etching technique or a wet etching technique, through the photolithography or electron lithography mask. Dry etching provides vertical sidewalls after etching. The etch must pass completely through the oxidation layer 9.

The photolithography or electron lithography mask is then removed and wet oxidation is performed. This may be achieved by exposing the etch structure to flowing steam in a furnace at approximately 400° C. Process temperatures can vary from 380° to 450° C.

An apparatus of the type shown in FIG. 2 will be used.

In the apparatus of FIG. 2, a heating mantle 21 is provided. The heating mantle has a first inlet port 23 to the heating mantle 21 into which de-ionised water is supplied. N₂ gas is then provided to the heating mantle through second input/output port 25.

Steam then comes out of the inlet/outlet port 25. The steam is then fed into tube furnace 27. The sample structure 29 which is to be oxidised, is located in tube furnace 27. Gases are exhausted out of port 31 of tube furnace.

Oxidisation affects the oxidation layer 9. The oxidisation proceeds laterally through the exposed sidewalls 41. The extent to which the oxidised region encroaches into mesa 42 is controlled adjusting the oxidation time such that a core 43 of un-oxidised material remains at the middle of the oxidation layer 9.

The central portion of the waveguide, as defined by said unoxidised core has a relatively high effective refractive index compared to the oxidised regions surrounding it, resulting in confinement of the optical mode to this region. The mode is also vertically confined to this region by the Bragg mirrors. This allows it to guide light along the length of the structure. The width of this unoxidised core and the thickness of the oxidation layer 9 and GaAs layer 7 can be tuned to match the wavelength of the light to be guided.

The inventors have found that the control can be enhanced with respect to AlAs oxidation layer by using oxidation layers, or regions with an Al content of ˜90%. This reduces the oxidation rate and hence allows for greater temporal precision in oxidation time.

A single AlAs oxidation layer would oxidise at a rate of ˜1 μm/min at an oxidation temperature of 400° C. A layer of Al_{0.98}Ga_{0.02}As of similar thickness would oxidise at a rate of ˜0.5 μm/min whilst a layer of Al_{0.98}Ga_{0.10}As again of similar thickness would oxidise at a rate of ˜0.1 μm/min.

After oxidation, a brief anneal in a dry ambient atmosphere may be necessary. This produces the structure shown in FIG. 1.

Other forms of waveguide will be explained later in the description.

The oxidation layer 9 may further comprise more than one layer with varying Al content which would oxide at variable rates giving control over profile of the oxide layer at the waveguide core.

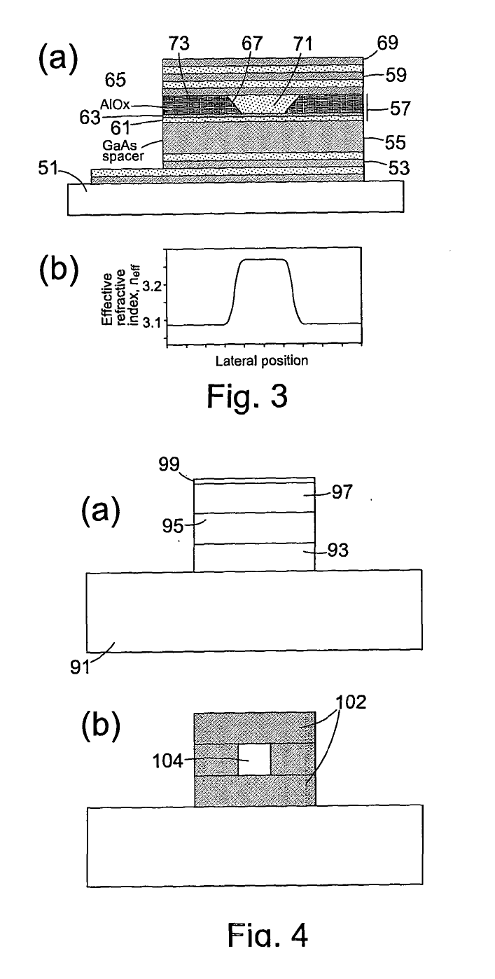

FIG. 3a shows a further semiconductor structure which by selective oxidation of a multi-layer region engineers the refractive index distribution in the structure to form a waveguide.

The structure is formed on a GaAs substrate 51. Lower Bragg mirror 53 is then formed overlying and in contact with substrate 51. GaAs layer 55 is then formed overlying and in contact with lower Bragg mirror region 53. Oxidation region 57 is then formed overlying and in contact with GaAs layer 55 and upper Bragg mirror 59 is then formed overlying and in contact with oxidation region 57.

In this particular embodiment, oxidation region 57 comprises three AlGaAs regions of distinct composition (61, 63, 65) such that oxidation produces a region of oxide with a tapered profile 67 as shown. In order to form such a taper, oxidation region could comprise Al_{0.7} Ga_{0.3}As 61, AlAs 63 and Al_{0.9}Ga_{0.1}As 65.

Oxidation proceeds rapidly along the thin AlAs layer. Reactants then diffuse vertically from this layer 63 into layers 61 and 65 at a rate dependant upon their Al content, resulting in non-uniform oxidation. By tuning the relative compositions of layers 61, 63 and 65 the taper angle, and hence lateral variation in effective refractive index may be engineered. A smooth variation in effective refractive index has the benefit of reducing optical scattering from high/low index interface.

The structure is patterned in the same way as described with reference to FIG. 1 using photolithography or electron lithography. The structure is to be patterned as a long ridge mesa. Mesa 69 is etched through the structure down to the GaAs substrate 51 in order to expose the sidewalls of oxidation layer 57.

The device is then oxidised as described with reference to FIG. 2 and the oxidation proceeds in the oxidation layer to form core 91 surrounded by oxide regions 73. The integration of the low refractive index AlOx layer again modifies the effective refractive index of the whole structure. This allows lateral confinement of photons to be realised in the waveguide 69.

FIG. 3b which lies directly below FIG. 3a shows the effective refractive index profile of the structure. The x-axis of FIG. 3b corresponds directly to the distance along the bottom of the mesa shown in FIG. 3a. It can seen that in the cladding region has a lower effective refractive index than the core, and that there is a smooth transition between the two due to the tapered oxide profile.

FIG. 4 shows a further structure in which optical confinement is achieved in both lateral and vertical directions by means of the selective oxidation of a number of oxidation layers.

FIG. 4a shows the layer structure of the device prior to oxidation. The structure is formed on a GaAs substrate 91. Overlying and in contact with said substrate 91 is first oxidation layer 93. Overlying and in contact with said first oxidation layer 93 is second oxidation layer 95 which is of a lower Al content than first oxidation layer 93. Overlying and in contact with said second oxidation layer 95 is third oxidation layer 97, which is of the same composition as said first oxidation layer 93. Overlying and in contact with said third oxidation layer is GaAs cap layer 99.

In this example, first and third oxidation layers 93, 97 have Al content 98% and second oxidation layer 95 Al content 95%. All three layers must have Al content >70% in order for oxidation to proceed.

The structure is patterned in the same way as described with reference to FIG. 1 using photolithography or electron lithography. The structure is to be patterned as a long ridge mesa. Mesa is etched through the structure down to the GaAs substrate 91 in order to expose the sidewalls of all oxidation layers 93, 95, 97.

The device is then oxidised as described with reference to FIG. 2 and the oxidation proceeds into all three oxidation layers, as shown in FIG. 4b. The relatively higher content of first and third oxidation layers 93, 97, results in complete oxidation of these layers 102. The lower oxidation rate of second oxidation layer 95, due to the reduced Al content in this layer, is only partially oxidised, resulting an unoxidised core 104 at the centre of the stripe along which photons may be guided.

Following oxidation, the GaAs cap layer 99 may be removed by chemical etching.

In accordance with an embodiment of the present invention, a quantum dot is provided in a layer structure with the waveguide and the structure is configured such that the quantum dot output photons which can then be guided by the waveguide.

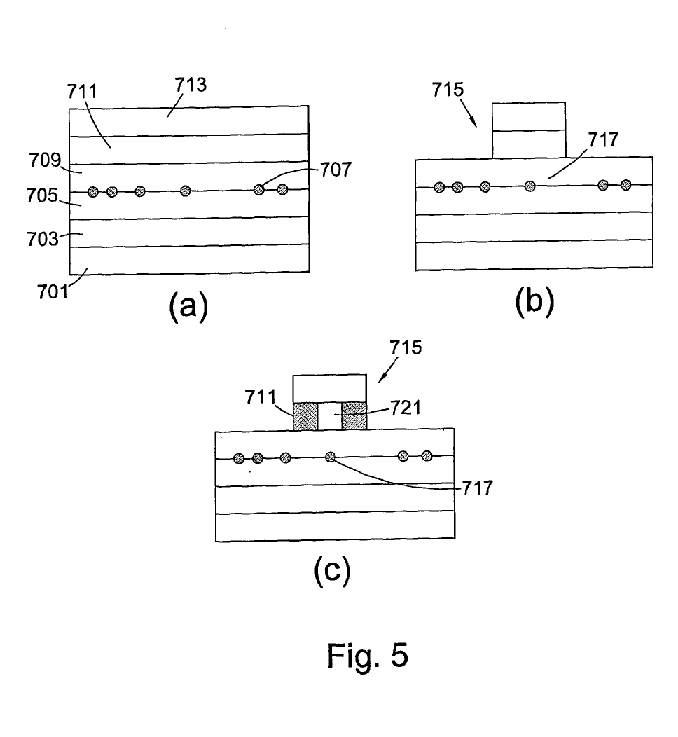

FIGS. 5a-c show the basic fabrication stages of such a device.

In FIG. 5a, a layer structure is formed comprising a plurality of quantum dots 707.

The layer structure is formed on GaAs substrate 701. Overlying and in contact with GaAs substrate 701 is lower mirror layer 703. Lower mirror layer 703 comprises a plurality of alternating layers of contrasting refractive index to form a Bragg mirror. In this example, said layers are GaAs and AlGaAs, but said Bragg mirror could incorporate one or more dielectric layers.

Overlying and in contact with lower mirror layer 703 is lower cavity layer 705. Lower cavity layer 705 comprises GaAs. Next, a quantum dot layer 707 is formed. The dots may be formed from InAs. To form the dots, a very thin layer, for example, a few mono layers InAs is deposited overlying lower cavity layer 705. Due to the strain of the growth interface, this thin layer 707 forms into a plurality of isolated quantum dots.

Overlying and in contact with quantum dot layer 707 is upper GaAs cavity layer 709.

Overlying and in contact with upper cavity layer 709 is oxidation layer 711. Overlying and in contact with oxidation layer 711 is upper mirror layer 713, which comprises a plurality of alternating layers of contrasting refractive index. In this example said layers are again GaAs and AlGaAs, although said layers need not necessarily be the same as in said lower mirror layer 703.

The structure is then etched to form a mesa 715 as shown in FIG. 5b. Mesa 715 is carefully aligned such that it overlies a single quantum dot 717 with desirable characteristics. The desirable characteristics will be that photon emission from the dot can be resolved and also that the dot emits photons with a wavelength suitable for the cavity and the waveguide which is to be formed.

In order to identify such a quantum dot, it is possible to use photoluminescence measurements looking for dot emission. Once a quantum dot has been identified, the position of the quantum dot can then be marked, for example by use of laser lithography.

Another possibility for identifying a position of a quantum dot is to look for undulations in wafer surface which correspond to quantum dots below. The position of the dot could then be marked using local oxidation using the atomic force microscope (AFM) tip.

Another possibility is to prepattern the wafer with markers which allow the precise location of the identified dot to be noted in relation to the markers.

Once the position of the desired dot 717 has been identified, a mesa is then aligned with the quantum dot. If it is desired to produce a single long waveguide, then the mesa will be lined so that the selected quantum dot will be along the central axis of the waveguide.

FIG. 5c shows the structure of FIG. 5b after oxidation. During oxidation, the exposed sidewalls of layer 711 are oxidised to define waveguide core 721. Waveguide core 721 lies directly above selected quantum dot 717.

The oxidation of layer 711 serves to modulate the refractive index so that there will be guiding of the photons emitted from quantum dot 717.

The above shows one possible fabrication arrangement, but in further arrangements, it is possible to etch down through the dot layer and possibly through the lower mirror layer 703. Thus the mesa would extend down to layer 703. It is also possible to form the quantum dot in the layer which is to be oxidised.

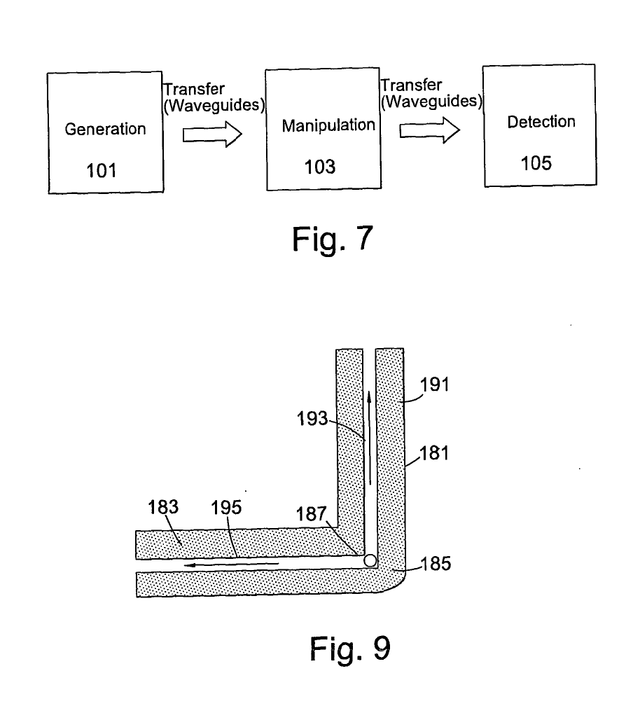

There are many variations on how to configure a quantum dot so that it will emit radiation. One possible variation is to arrange the structure shown in FIG. 7a to be a p-i-n structure where the lower layers are p-type and the upper layers are n-type or vice versa.

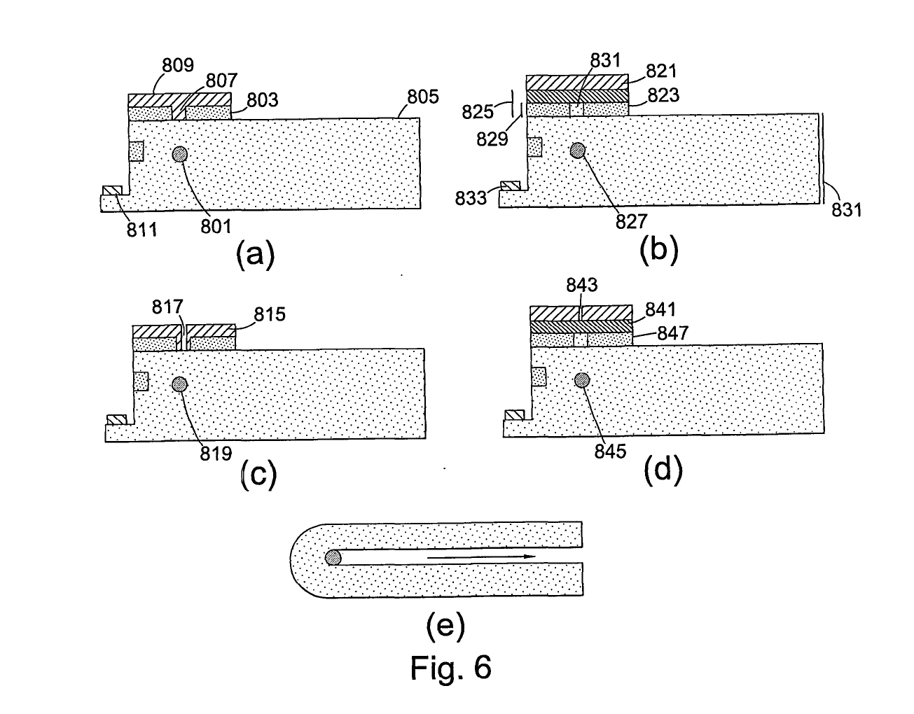

FIGS. 6a-e shows some further variations on the structure of FIG. 5c.

FIG. 6a illustrates a further embodiment of a structure in accordance with an embodiment of the present invention. The semiconductor structure comprises a plurality of layers, some of which may be doped in order to be n- and p-type to facilitate electrical excitation of the structure.

The structure contains a single quantum light source at a pre-determined position such that only that quantum light source is excited—either by electrical and/or optical means.

The position of the quantum dot is known prior to device fabrication—either through experimental investigation of the sample to identify said source's location, or by means of additional processes performed during sample growth such that said quantum light source is itself located at a pre-determined position. Subsequently, the position of the waveguide can be accurately aligned to said quantum light source by means of high-resolution lithography techniques such as electron.

In the embodiment of FIG. 6a of the source, the quantum dot 801 in the finished structure is electrically excited by means of direct carrier injection. The semiconductor structure is fabricated as described with reference to FIGS. 5a to 5c. A dielectric layer 803 is deposited onto the oxidised structure 805 and patterned with an aperture 807 in order to confine the electrical contact to a micron- or sub-micron-sized region.

Said aperture is sized so as to restrict the current path to the chosen single quantum light source. Said dielectric layer 803 may comprise, but is not limited to silicon dioxide or silicon nitride deposited via some gas- or plasma-based process (CVD, PECVD), by means of thermal or electron-beam evaporation or through a sputter-coating process. Alternatively, said dielectric film 803 could be a spin-on dielectric material such as “spin-on-glass”, or a spin-on dielectric which may be subsequently patterned by exposure to an electron-beam or deep-ultraviolet radiation. If necessary, said dielectric layer may then be etched away using either a wet chemical etch, or by means of a dry, plasma-based process.

Finally a metal layer 809 is deposited and patterned, typically by a lift-off process. Said metal layer 809 may comprise several elements, depending upon the nature of the electrical contact to be produced. In order to contact an n-type semiconductor layer, metal layers such as, but not limited to AuGeNi or PdGe may be employed. In order to contact p-type semiconductor, metal layers such as, but not limited to AuBe, InZn, or Al may be used. A subsequent thermal anneal may be employed if required. A second metal layer 811 would then be employed to create a lower electrical contact to the structure.

FIG. 6b illustrates a variation on the embodiment of FIG. 6a. Here said metal contact 815 is patterned such that it contains an aperture 817, such that the quantum light source 819 may be optically excited by means of a light beam focussed to pass through the clear aperture 817 in the otherwise opaque metal film 815.

FIGS. 6c and 6d illustrate two further embodiments of the device. As with the embodiments in FIGS. 6a and 6b, two variants are presented—one with a completely opaque metal contact 821 and a second with metal contact 841 which contains an optically transparent aperture 843 to facilitate optical excitation of the embedded quantum light source 845. In the embodiments illustrated in FIGS. 6c and 6d, the dielectric regions 823, 847 respectively, are produced by a further wet oxidation step.

A mesa 825 is defined such that the centre of the dielectric annulus 823 will be located directly in line with the pre-determined position of the embedded quantum light source 822. Mesa 825 is etched in order to expose oxidation layer 829. Said oxidation layer 829 is then partially oxidised through the exposed sidewalls of mesa 825 in order to form an unoxidised aperture 831 at the centre of the mesa. Mesa 831 is then defined, etched and oxidised and fabrication continues as for the embodiment described in FIG. 5a-5c. Metal layers 821 and 823 may then be deposited in order to contact doped semiconductor layers subject to the considerations applied with regard to FIG. 6a.

Fabrication of the embodiment illustrated in FIG. 6d would be accomplished in the same fashion as discussed with reference to FIG. 6c, with the exception of said upper metal layer 841 being patterned with said optically transparent aperture 843 in order to enable optical excitation.

FIG. 6e shows a plan view of the structures of FIGS. 6a to 6d.

The present invention is intended for use for making integrated quantum optical systems. In such systems, there will generally be three stages as shown in FIG. 7. These are generation 110 where the photons are generated, manipulation 103 where the photons are manipulated using a number of techniques and pass through components such as filters, beamsplitters, interferometers etc and detection where the photons are eventually detected. It is necessary to provide transport via waveguides between each of sections 101, 103, and 105.

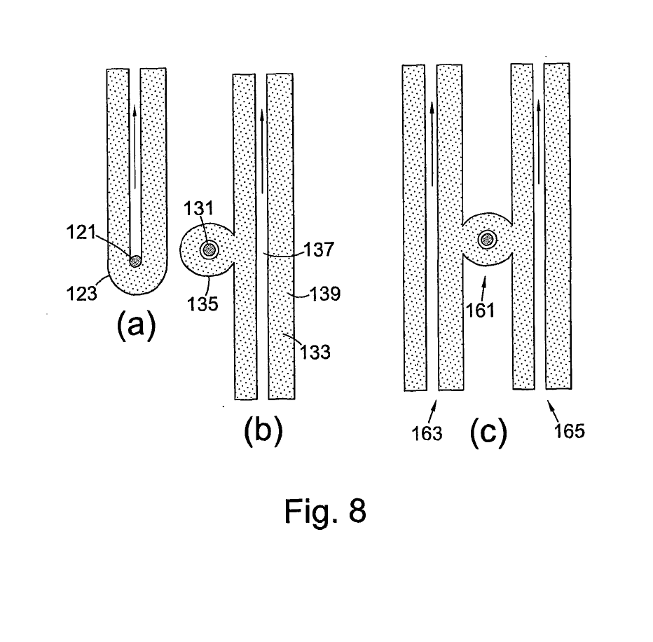

FIG. 8 schematically illustrates how the structures of the present invention with a waveguide can be incorporated to include a photon source such that generation and transfer of the photons away from the generating portion form manipulation can be achieved on a single integrated chip.

In FIG. 8a, a photon source 121 is incorporated into a waveguide 123 as described with reference to FIGS. 5 and 6. It is possible for the waveguide to be of the type described with reference to FIG. 4.

The waveguide 121 is formed from a ridge type mesa as previously described. The photon source which comprises a single active quantum dot is then provided in said waveguide such that the waveguide core will be aligned to the dot. In an embodiment the quantum dots are embedded in a GaAs layer, and in a further embodiment not in the layer to be oxidised. However, InAs dots can also be grown directly on AlGaAs.

The mesa is then oxidised in order for AlAs to form oxidised regions of the edges. The oxidation is timed so that the core of the waveguide 125 is formed of a suitable width in order to guide photons which are emitted from the photon source. The photons can then be guided into a region for manipulation as suggested in FIG. 7.

FIG. 8b shows a variation on the arrangement of FIG. 8a. Here, a photon source 131 which comprises a quantum dot is provided to the side of a strip waveguide 133.

The photon source 131 is provided within a low volume cavity 135. Photons which exit the low volume cavity 135 are coupled evanescently into strip waveguide 133.

A semiconductor layer structure is formed as previously described with an oxidisable layer. Typically, this layer will comprise AlAs or other high Al content layer. A quantum dot will be provided in the adjacent spacer layer.

A structure is then etched which is in the form of a long stripe with a circle attached to the stripe. The etch extends through the oxidation layer.

The structure is then oxidised as described above. The oxidation extends into circular region to define cavity 135. The oxidation also extends into stripe region 133 to define core region 137 surrounded by oxidised regions 139. FIG. 8c shows a further variation on the device shown in FIG. 8b. Here, a photon source 161 which comprises a quantum dot is provided to the side of strip waveguide one 163 and simultaneously to the side of strip waveguide two 165.

The layer structure of the photon source 161 is identical to photon source 131 of FIG. 6b. The layer structure of the two strip waveguides 163, 165 are identical to that of the strip waveguide 133 of FIG. 8b.

As in the device shown in FIG. 8b, photons which exit the low volume cavity are coupled evanescently into the adjacent strip waveguides 163, 165. By varying designing the device such that the coupling between the photon source 161 and strip waveguide one 163 is different to the coupling between photon source 161 and strip waveguide two 165, it is possible to produce two photon streams with different emission rates from a single source.

Recently, single photon sources are being used to produce entangled photons. FIG. 9 shows a semiconductor structure comprising a waveguide in accordance with an embodiment of the present invention which is configured for use with a quantum dot which outputs entangled photons. The structure comprises a first waveguide 181 which is orthogonal to a second waveguide 183. The waveguides join at vertex 185. Quantum dot 187 is provided with vertex 185.

The device is formed by forming a plurality of semiconductor layers with one of the layers being an oxidation layer which is capable of oxidation. A quantum dot is provided in an adjacent GaAs layer. A mesa is then etched which is in the form of a right angle with two orthogonal strips joining a vertex 185. The mesa is located such that a quantum dot is provided in the centre of the vertex.

The structure is then oxidised as described with reference to FIG. 2 to form oxidised region 191. Oxidised regions 191 extend into the structure and define the first and second waveguide core widths 193 and 195.

The size of the waveguide causes control to allow coupling to the photons emitted from photon source 187.

The neutral exciton states of quantum dot 187 have orthogonal dipoles in the plane of a sample which emit at slightly different energies. Such dipoles cannot emit along their axis so polarisation entangled photons from a bi-exciton or higher order exciton cascade cannot be coupled directly into the same waveguide. With the arrangement of FIG. 9, they are coupled directly into two orthogonal waveguides.

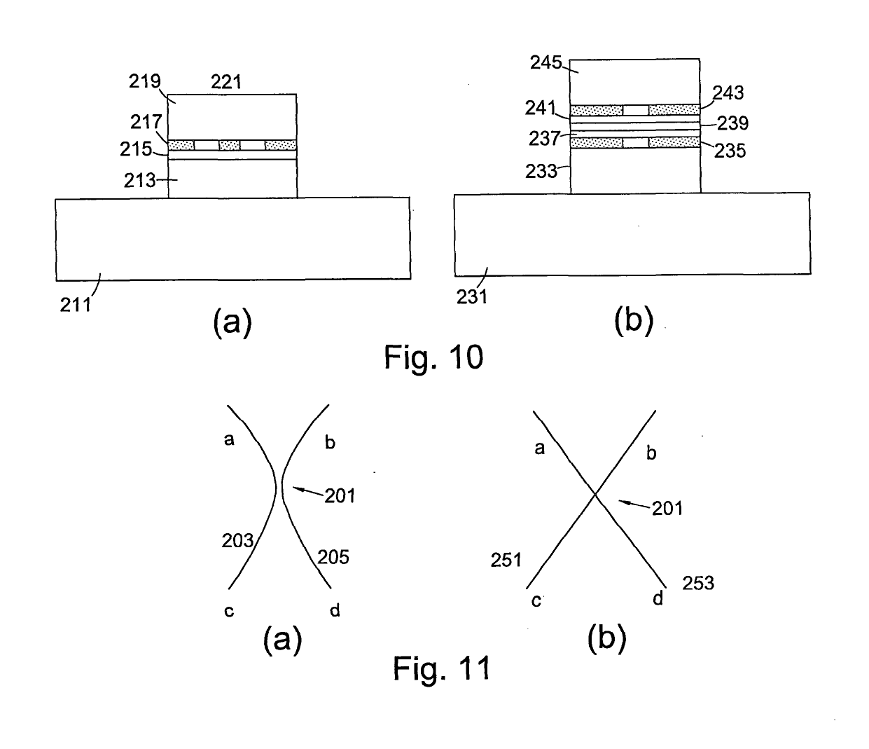

FIGS. 10a and 10b show examples of horizontally and vertically coupled waveguides. Photon sources of the type described with reference to FIGS. 4 to 9, may be incorporated in these waveguides.

FIGS. 10a and 10b show waveguide structures with two waveguides. Possible examples of the lateral arrangement for waveguides as shown in FIGS. 11a and 11b. The waveguides laterally are arranged so that there is a point 201 where the waveguides are closest. At this point, it is possible for evanescent coupling to occur between the waveguides. The coupling probability between the two waveguides will depend upon their separation and profile over their region of closest approach (interaction region). The smaller this separation and the longer the interaction region, the higher the probability of coupling between the two paths.

Referring to FIG. 11a, the waveguides 203 and 205 are arranged in a curved arrangement with the closest point 201 of the curves of waveguides 203 and 205 close enough to allow evanescent coupling.

This allows photons which enter a single waveguide at point A to either remain in the waveguide or transfer to the second waveguide 205 at point 201 therefore, the photon may emerge at either points C or D. Similarly, if photons enter at points A and B, they may mix at point 201 so that photons will be transferred between the waveguides which are outputted at points C and D. FIG. 11a relates to a horizontally coupled waveguide. FIG. 10a shows a possible layer structure.

In FIG. 10a, GaAs substrate 211 is formed first. Then, a layer structure comprising a lower Bragg reflector 213, formed overlying and in contact with said Bragg layer is GaAs layer 215 overlying and in contact with said GaAs layer is oxidation layer 217 which in this particular example is AlAs overlying and in contact with said AlAs layer is upper Bragg mirror 219.

The structure is etched to form mesa. Mesa 221 will be in the form of a curved X. The structure is then oxidised as described with reference to FIG. 2. This curved X upon oxidation allows the formation of the curved X lateral waveguide arrangement as shown in FIG. 11a.

FIG. 10b shows a vertically coupled waveguide arrangement.

The structure comprises GaAs substrate 231. Overlying and in contact with GaAs substrate 231 is formed lower Bragg reflector 233. Overlying and in contact with said lower Bragg reflector is first oxidation layer 235. Overlying and in contact with said first oxidation layer 235 is first GaAs layer 237. Overlying and in contact with said first GaAs 237 is middle spacer layer 239, comprising non-oxidisable material of lower refractive index than the GaAs layer 237. In this particular example Al_{0.5}Ga_{0.5}As. Overlying and in contact with said middle layer 239 is second GaAs layer 241. Overlying and in contact with said second GaAs layer 239 is second oxidation layer 243. Overlying and in contact with said second oxidation layer 241 is upper Bragg reflector 245.

The structure is etched to form a mesa such that the etch passes through upper oxidation layer 243 but not passing through middle spacer layer 239. The structure is then oxidised as described with reference to FIG. 2. The structure is then etched a second time, now passing completely through lower oxidation layer 235. The structure is then oxidised a second time as described with reference to FIG. 2.

As oxidation is a diffusion-based process, and as diffusion of oxidation reactants takes place extremely slowly through previously oxidised material, the lateral extent of the oxidised material formed in layer 243 following the first oxidation remains unaltered.

The arrangement of FIG. 10b is shown laterally in FIG. 11b. Again as described with reference to FIG. 11a, this allows a photon which is inserted into first waveguide 251 at point A to transfer into second waveguide 253 at the point where the waveguides are closest 201. Similarly, if photons enter the first waveguide 251 at points A and B and the second waveguide 253 at point B, the photons can then couple at point 201 and a mixture will be outputted at points C and D. By controlling the shape, separation and hence “interaction length” of the two waveguides, photon transfer could be tuned to any desired splitting ratio, including 50:50.

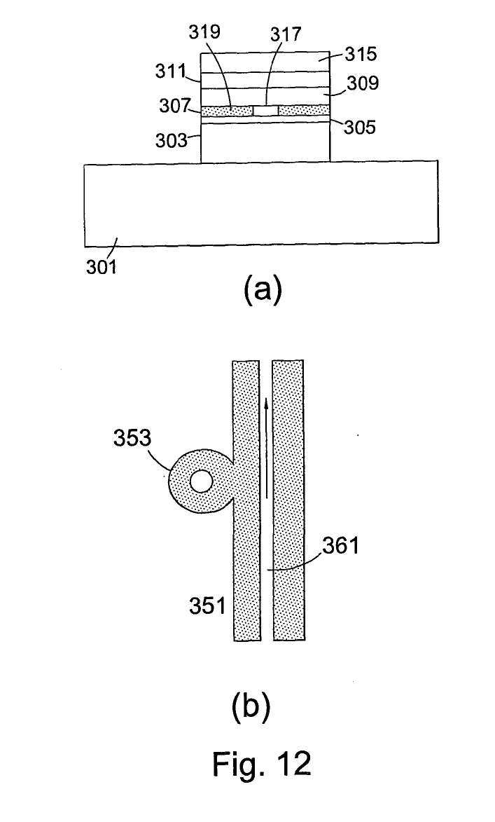

FIGS. 12a and b show how the present invention may be used for fabrication of a phase shifting element. A photon source (not shown) is incorporated.

In FIG. 12a electro-optical effects are used to change the refractive index and introduce a phase shift into the waveguide. The structure comprises GaAs substrate 301. Overlying and in contact with said substrate is lower Bragg mirror 303. GaAs layer 305 is then provided overlying and in contact with said lower Bragg layer 303. Oxidation layer is then provided overlying and in contact with said GaAs layer 305. Doped first Bragg mirror 309 is then provided overlying and in contact with said oxidation layer 307. A quantum well layer comprising GaAs 311 is then formed overlying and in contact with said first doped Bragg mirror 309. Doped upper Bragg mirror 315 is then provided overlying and in contact with said quantum well layer 311. Quantum dots (not shown) are formed within GaAs layer 305.

The first and second doped Bragg mirrors allow the bias across a quantum well to be varied. This allows the quantum well to stark shift in its energy population. This in turn changes the refractive index of a mode formed in the waveguide 305 either by inducing absorption or causing a phase change. The structure is fabricated as described previously with a mesa being etched to form a waveguide structure of any of the types previously described. The structure is then oxidised as described in FIG. 2 so that an unoxidised core 317 is provided flanked by oxidised regions 319. The size of the core 317 can be carefully controlled for the photons which the waveguide is intended to carry.

FIG. 12b shows a variation on the device of FIG. 12a but again is used for phase shifting.

The structure is similar to that described with reference to FIG. 8b.

The structure comprises a stripe type waveguide 351 which is adjacent an element 353. In this example, the element is a cavity. However, the element could also be a photon absorber or a heating pad. The presence of cavity 353 forms a local variation in the refractive index of waveguide 351 to allow the phase to be changed.

As previously described, the device may be fabricated from a structure of semiconductor layers comprising a layer with a high Al content which may be oxidised. A mesa structure is then etched in the form of a line with a circle adjacent to the line. The structure is then oxidised as described with reference to FIG. 2 in order to form the structure of FIG. 12b with a waveguide 353 having an unoxidised core 361 and a circular cavity.

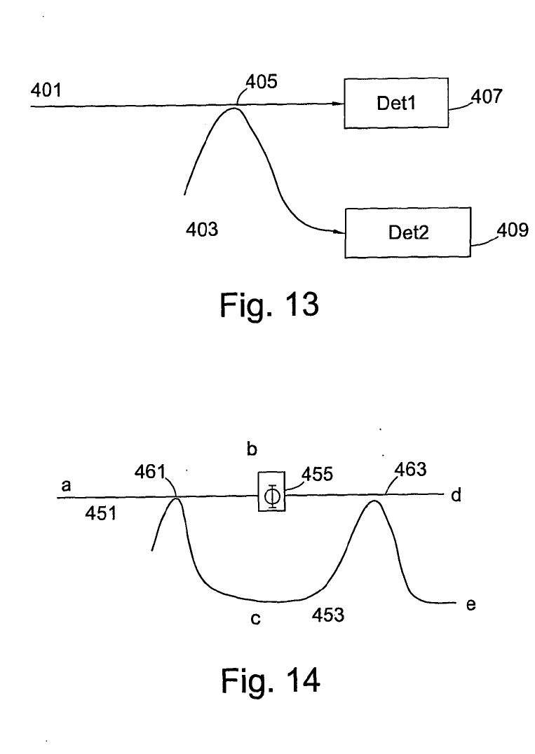

These embodiments of the present invention allow the integration on a single chip of many useful devices. FIG. 13 shows schematically a device arrangement which can be used to produce an on-chip quantum random number generator or an on-chip facility for a Hanbury-Brown Twiss measurement. The device comprises a first waveguide 401 and a second waveguide 403. The waveguides are arranged so that they have a section 405 where they are close enough to allow evanescent coupling. One end of waveguide 401 terminates in detector 407 and one end of second waveguide 403 terminates in second detector 409. A single photon is input into first waveguide 401 from a quantum dot which is configured to supply photons to the waveguide. When the photon reaches region 405, it has a 50:50 chance of either remaining in waveguide 401 or switching to second waveguide 403. Therefore, a count is randomly detected at either detector one 407 or detector two 409. This allows the system to be used as a single photon detector.

The system may be fabricated using a coupled waveguide as explained with reference to FIGS. 10a to 11b. A photon structure is provided in one of the waveguides as described with reference to any of FIGS. 5 to 8b.

The detectors may be fabricated on the same chip as the waveguides.

The system in FIG. 13 may also be used as a Hanbury-Brown and Twiss Interferometer. For this, processor is connected to both detector 1 and detector 2 in order to correlate the outputs and measure the statistics.

FIG. 14 shows an arrangement which can be used for guiding photons or for quantum cryptography.

The arrangement comprises a first waveguide 451 and a second waveguide 453. A quantum dot acting as a photon source is provided in one of the waveguides. A phase shifting element 455 is provided in first waveguide 451. The second waveguide 453 is curved so that it has two points where it is close enough to waveguide 451 to allow evanescent coupling between the waveguides. At the first point 461, a 50:50 beamsplitter is essentially formed and at the second point 463, a 50:50 beamsplitter is formed. The coupled waveguides 451 and 453 may be fabricated as described with reference to FIGS. 12a to 12b.

The phase shift element 455 may be fabricated in one waveguide as described with reference to FIGS. 10a and 10b. If the distance between the two coupling points 461, 463 is the same regardless of whether the photon follows the first waveguide 451 or the second waveguide 453, then if no phase shift is introduced by phase shifting element 455, a photon will exit the interferometer formed by the first waveguide 451 and the second waveguide 453 at point d.

If the phase shift element 455 introduces a phase difference of 180°, then the photon will exit the structure via arm e. If the length of the first waveguide 451 between the two coupling points 461, 463 is less than the length of the second waveguide 453 between the second coupling points 461, 463, the photons which leave by (say) point D are in two “time-bins” separated by the time delay, the relative phase can be changed using the phase shifting element 455 for generating time-bin entangled photons. This is applications as an interferometer in quantum cryptography. As these waveguides are birefringent, they are of most use when using time and phase encoding.

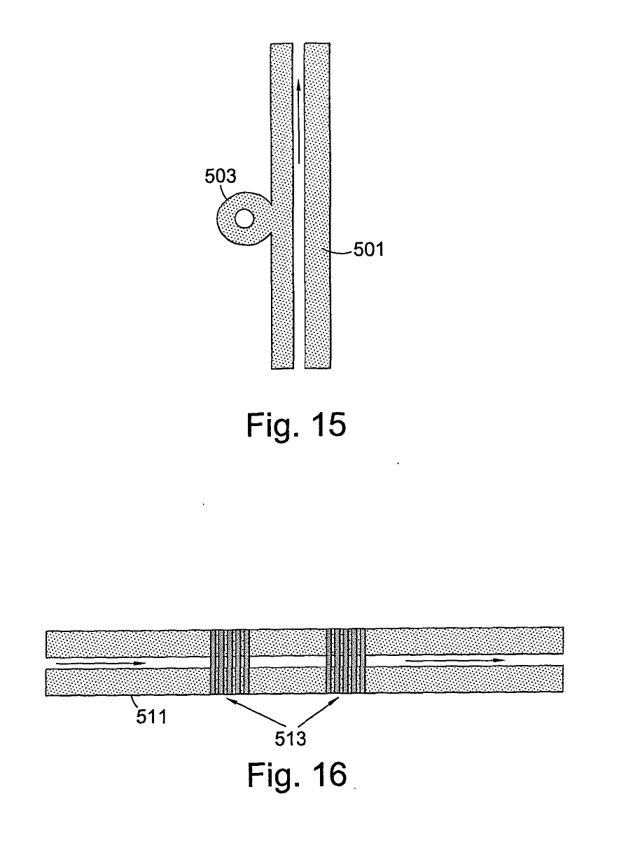

FIG. 15 illustrates the present invention as used as a photonic transistor. The photonic transistor can be fabricated as shown in FIG. 15 with a stripe type waveguide 501 with a circular cavity 503 adjacent to the waveguide. Transmission through the waveguide is controlled by the presence or absence of a photon in the evanescently coupled cavity 503. Therefore, guided photons are able to probe the occupancy of the cavity acting as a photonic transistor. The waveguide and cavity could be horizontally or vertically coupled.

Here, the photon occupancy of the cavity would be controlled by a further, independent light source. Said light source could be an external light source. Alternatively said light source could be a second, on-chip, waveguide structure. Thus, a quantum dot may be provided in the waveguide, in the cavity or in both structures.

FIG. 16 shows an example of an optical filter element.

The filter comprises a stripe waveguide as described with reference to FIG. 1. The stripe waveguide 511 is then patterned with a plurality of mirrors 513 formed from etched ridges. The structure will work to only pass photons having a certain range of wavelengths. The range of wavelengths passed could be changed by a localised heating.

A nearby cavity could be used to modify the local refractive index of a portion of this structure. In this case the elements of the structure would become mismatched—however it might be possible to use this to achieve some degree of tuning. Likewise, local heating would have a similar effect. Photons may be provided using a quantum dot incorporated in said structure.

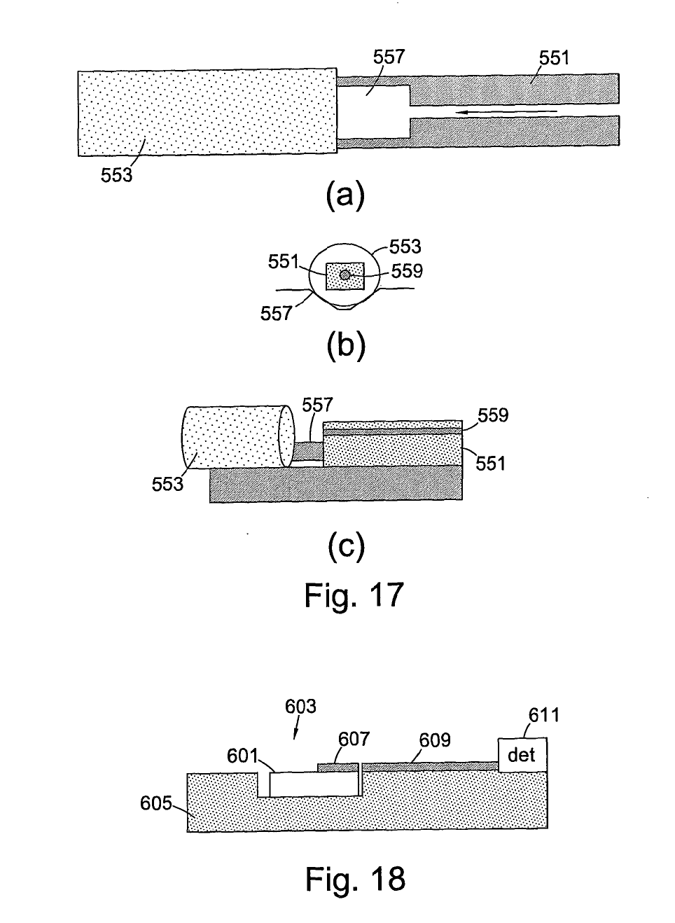

FIGS. 17a,b,c indicate how a waveguide with a photon source (not shown) according to the present invention may be coupled to an optical fibre. The waveguide 551 is coupled to optical fibre 553 by etching a groove 557 which is aligned with the waveguide in which to look at the fibre. After integration, the waveguide optical mode 559 becomes aligned on-axis with the optical fibre 553.

Chip-to-chip coupling is shown in FIG. 18. First chip 601 is directly bonded into recess 603 of second chip 605. First chip 601 has a first element 607 and second chip 605 has a second element 609. Second chip 605 also has a detector 611. The first chip 601 comprises a quantum dot configured to emit photons into a waveguide on said first chip 601.

The waveguides can be directly aligned allowing efficient photon coupling between the chips. The ends of the waveguides to be mated would be aligned using a micropositioning device and then bonded into place. The void between the aligned waveguides may be left as an air gap. Alternatively an index-matched coupling medium may be introduced to both improve coupling and structural integrity.

Both chips could contain several elements, including source, manipulation and detection components.

The above allows the coupling of lateral emission into another waveguide on a separate chip by a way for bonding. Units could be built up allowing direct interlinking of sources, control/logic units and detectors. The chips need not be the same material allowing interlinking between III/V and silicon structures.

Devices and methods in accordance with embodiments of the present invention allow an integrated circuit to be produced on a single chip which gives improved mechanical stability and a small device footprint.

While certain embodiments have been described, these embodiments have been presented by way of example only, and are not intended to limit the scope of the inventions. Indeed, the novel methods and structures described herein may be embodied in a variety of other forms; furthermore, various omissions, substitutions and changes in the form of the methods and structures described herein may be made without departing from the spirit of the inventions. The accompanying claims and their equivalents are intended to cover such forms or modifications as would fall within the scope and spirit of the inventions.

1. A semiconductor structure comprising a waveguide, said semiconductor structure comprising a plurality of layers, at least one of which being partially laterally oxidised, said laterally oxidised material modifying the lateral effective refractive index with said structure in order to form a waveguide within said structure, the structure further comprising a quantum dot, said quantum dot being configured to emit photons into said waveguide, said waveguide being configured such that it guides the output from a single quantum dot.

2. A semiconductor structure according to claim 1, wherein said structure comprises a mesa and said quantum dot is provided along a central line through said mesa.

3. A semiconductor structure according to claim 1, further comprising an electrical contact, said electrical contact being configured supply carriers to said single quantum dot.

4. A semiconductor structure according to claim 3, configured such that said electrical contact only supplies carriers to said single quantum dot.

5. A semiconductor structure according to claim 1, further comprising an aperture aligned with said single quantum dot to allow irradiation of said quantum dot.

6. A semiconductor structure according to claim 1, wherein said device comprises at least one compound selected from InAlGaAs, GaAs, AlGaAs, InAs, InAlAsP, InP or InAlAs.

7. A semiconductor structure according to claim 1, wherein said waveguide is configured such that a single one propagating mode is formed.

8. A semiconductor structure according to claim 1, wherein the waveguide islocated vertically between a pair of cladding layers, and said waveguide is itself partially oxidised.

9. A semiconductor structure according to claim 1, further comprising a component configured to receive photons, said waveguide being configured to guide said photons towards said component.

10. A semiconductor structure according to claim 9, wherein said component is a detector, comprising a plurality of layers configured for the absorption of photons.

11. A semiconductor structure according to claim 10, wherein said detector comprises a plurality of quantum dots, an absorber layer and electrical contacts such that an electrical output is produced upon the detection of incident photons via carrier multiplication.

12. A semiconductor structure according to claim 1, comprising a beam splitter; said beam splitter comprising first and second waveguides, provided within at least one layer and being laterally confined in the plane of the layers by an oxidised material, said waveguides being coupled at at least one point along their length.

13. A semiconductor structure according to claim 12, comprising a random number generator, said random number generator comprising said beam splitter configured to operate as a 50/50 splitter, a photon source coupled to an end of said first waveguide, a detector coupled to the other end of said first waveguide and a second detector coupled to the end of said second waveguide where photons will exit.

14. A semiconductor structure according to claim 1, comprising an interferometer; said interferometer comprising first and second waveguides, provided within at least one layer and being laterally confined in the plane of the layers by an oxidised material, said waveguides being coupled at two points along their length, with a phase shifting element being provided in at least one of the waveguides between said coupling points.

15. A semiconductor structure according to claim 1, comprising a phase shifting element, said phase shifting element comprising an electrical contact configured to affect the electric field in a part of the waveguide.

16. A semiconductor structure according to claim 1, comprising a phase shifting element, said phase shifting element comprising a photon cavity in proximity to said waveguide to locally change the refractive index in a part of the waveguide.

17. A semiconductor structure according to claim 1, comprising a photonic transistor, said transistor comprising a photon cavity in proximity to said waveguide to locally change the refractive index in a part of the waveguide.

18. A semiconductor structure according to claim 1, comprising a filter, said filter comprising a plurality of opposing mirrors provided across said waveguide.

19. A semiconductor structure according to claim 1, comprising first and second orthogonal waveguides which are joined at a vertex and a source of entangled photons provided at said vertex.

20. A method of fabricating a semiconductor structure comprising a waveguide, said method comprising:
forming a plurality of semiconductor layers incorporating an oxidisable layer and a quantum dot in one of said layers;
etching a pattern in said oxidisable semiconductor layer aligned with said quantum dot; and
oxidising said oxidisable semiconductor layer to produce a waveguide which is laterally bounded by the effective refractive index variation due to the presence of said oxidised material, the quantum dot being aligned with said waveguide such that said quantum dot outputs photons to said waveguide.
